(19) United States
(12) Patent Application Publication
(10) Pub. No.: US 2006/0214261 A1
(43) Pub. Date: Sep. 28, 2006

(54) Anti-fuse circuit for improving reliability and anti-fusing method using the same

(76) Inventors: Hyung-Sik You, Suwon-si (KR); Seouk-Kyu Choi, Hwaseong-si (KR); Jong-Won Lee, Seoul (JP); Hyun-Seok Lee, Seoul (KR)

Correspondence Address: F. CHAU & ASSOCIATES, LLC, 130 WOODBURY ROAD, WOODBURY, NY, 11797, US

(21) Appl. No.: 11/322,148

(22) Filed: Dec. 29, 2005

(30) Foreign Application Priority Data
Feb. 4, 2005 (KR) 2005-10581

(51) Int. Cl. H01L 29/00

(52) U.S. Cl. 257/530

(57) ABSTRACT

An anti-fuse circuit includes an anti-fuse device and an electric field control unit. The anti-fuse device is formed having a MOS structure including a first junction, a second junction and a gate terminal. The electric field control unit performs a control operation so that an electric field is formed in the anti-fuse device at the time of an anti-fusing operation. Electric fields formed at the first and second junctions of the anti-fuse device are separately controlled, so that breakdown can occur at two points. Further, the gate terminal of the anti-fuse device is implemented in the form of a band-shaped closed circuit.

This application claims priority to Korean Patent Application No. 10-2005-0010581, filed on Feb. 4, 2005, in the Korean Intellectual Property Office, the disclosure of which is incorporated herein, in its entirety, by reference.

### BACKGROUND OF THE INVENTION

1. Field of the Invention

The present invention relates to an anti-fuse circuit and, more particularly, to an anti-fuse circuit including an anti-fuse device having a MOS structure.

2. Description of Related Art

An anti-fuse device functions as a switch for connecting two electrodes to each other. The anti-fuse uses a breakdown in an electrode/insulator/electrode structure to achieve the connection between electrodes. The function of a semiconductor device can be expanded with the anti-fuse device, even after the internal wiring of the semiconductor device has been completed.

FIG. 1 is a view showing a conventional anti-fuse circuit 100. An anti-fuse device 110 of the anti-fuse circuit 100 of FIG. 1 is implemented having a metal oxide semiconductor (MOS) structure. The anti-fuse device 110 includes a first junction 111, a second junction 112 and a gate terminal 113. At the time of an anti-fusing operation, a high voltage is applied to a pad 114, and a fuse selection signal SEL and a fusing signal FUSE that are provided to an electric field control unit 120 make a transition to a logic H level, as shown in FIG. 2. In this case, an electric field Ef is formed between the gate terminal 113 and first and second junctions 111 and 112 of the anti-fuse device 110. An insulating layer 115 of the anti-fuse device 110 is broken down by the electric field Ef.

In the anti-fuse circuit 100 of FIG. 1, the first and second junctions 111 and 112 of the anti-fuse device 110 are connected to each other. Therefore, at the time of an anti-fusing operation, if breakdown of the insulating layer 115 occurs at one point, breakdown does not occur at the other point. If the breakdown occurs in the regions between the gate terminal 113 and the first junction 111 or in the region between the gate terminal 113 and the second junction 112, the region not broken down is controlled by a high voltage applied to the gate terminal and an electric field is not-formed. In this case, there may occur the case in which an insulator, having broken down at only one point, continues to operate.

Therefore, the conventional anti-fuse circuit 100 of FIG. 1 is problematic in that it is unreliable.

Further, FIG. 7 is a view showing an anti-fuse circuit 500 including an anti-fuse device 510. In FIG. 7, the layout of the anti-fuse device 510 is shown, and an electric field control unit 520 is shown in the form of a block.

A gate terminal 513 of the anti-fuse device 510 of FIG. 7 is formed in a straight-line shape. A uniform electric field is formed at the gate terminal 513 at the time of an anti-fusing operation. In the anti-fuse device 510 of FIG. 7, a voltage difference between two junctions 511 and 512 needs to be high to cause the breakdown of the gate terminal.

### SUMMARY OF THE INVENTION

In accordance with an embodiment of the present disclosure, an anti-fuse circuit includes an anti-fuse device and an electric field control unit. The anti-fuse device is formed having a MOS structure including a first junction, a second junction and a gate terminal. The electric field control unit performs a control operation so that an electric field is formed in the anti-fuse device at the time of an anti-fusing operation. The electric field control unit is driven so that formation of an electric field between the gate terminal and first junction of the anti-fuse device and formation of an electric field between the gate terminal and second junction of the anti-fuse device are separately controlled.

In accordance with an embodiment of the present disclosure, an anti-fuse circuit includes an anti-fuse device and an electric field control unit. The anti-fuse device is formed having a MOS structure including a first junction, a second junction and a gate terminal. The electric field control unit performs a control operation so that an electric field is formed between the first and second junctions of the anti-fuse device at the time of an anti-fusing operation. The gate terminal of the anti-fuse device is implemented in the form of a band-shaped closed circuit.

According to an embodiment of the present disclosure, an anti-fusing method using an anti-fuse circuit that includes an anti-fuse device formed having a MOS structure including a first junction, a second junction and a gate terminal, comprises forming an electric field between the gate terminal and the first junction of the anti-fuse device at a first time point, and forming an electric field between the gate terminal and the second junction of the anti-fuse device at a second time point, wherein the first and second time points have a predetermined time interval therebetween.

The method comprises applying a first voltage to the first junction in response to a first fusing signal. The method further comprises applying a second voltage to the second junction in response to a second fusing signal.

Forming the second electric field further comprises deactivating the first electric field.

### BRIEF DESCRIPTION OF THE DRAWINGS

The present disclosure will be more clearly understood from the following detailed description taken in conjunction with the accompanying drawings in which:

FIG. 1 is a view showing a conventional anti-fuse circuit;

FIG. 2 is a view showing the formation of an electric field in the anti-fuse circuit of FIG. 1;

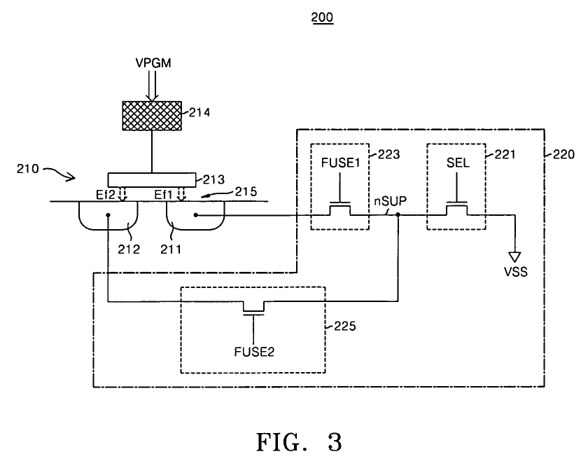

FIG. 3 is a view showing an anti-fuse circuit according to an embodiment of the present disclosure;

FIG. 4 is a view showing the formation of an electric field in the anti-fuse circuit of FIG. 3;

FIG. 5 is a view showing an anti-fuse circuit according to an embodiment of the present disclosure, which shows a modified embodiment of the anti-fuse circuit of FIG. 3;

FIG. 6 is a view showing an anti-fuse circuit according to an embodiment of the present disclosure, which shows an embodiment for supplementing the anti-fuse circuit of FIG. 5;

FIG. 7 is a view showing an anti-fuse circuit including an anti-fuse device; and

FIGS. 8 and 9 are views showing anti-fuse circuits according to embodiments of the present disclosure.

### DETAILED DESCRIPTION OF PREFERRED EMBODIMENTS

Reference now should be made to the drawings, in which the same reference numerals are used throughout the different drawings to designate the same or similar components. In the following description of the present disclosure, detailed descriptions of well-known functions and construction may by omitted.

Hereinafter, embodiments of the present disclosure will be described in detail with reference to the attached drawings.

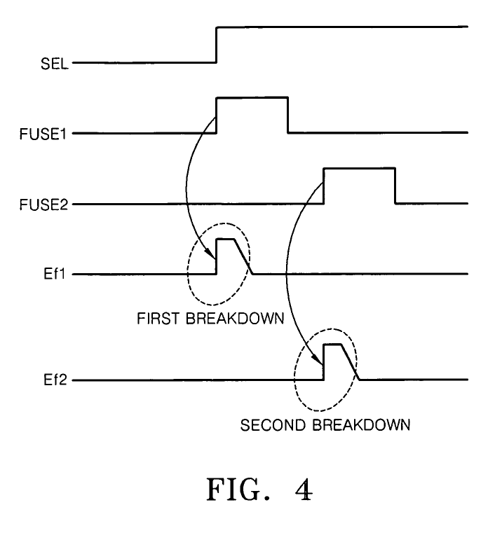

FIG. 3 is a view showing an anti-fuse circuit 200 according to an embodiment of the present disclosure. Referring to FIG. 3, the anti-fuse circuit 200 includes an anti-fuse device 210 and an electric field control unit 220.

The anti-fuse device 210 is formed having a MOS structure including a first junction 211, a second junction 212 and a gate terminal 213. An insulating layer 215 is formed between the gate terminal 213 and the first and second junctions 211 and 212. At a time of an anti-fusing operation, a program voltage VPGM is applied to the gate terminal 213 of the anti-fuse device 210 through a pad 214. The program voltage VPGM is a high voltage.

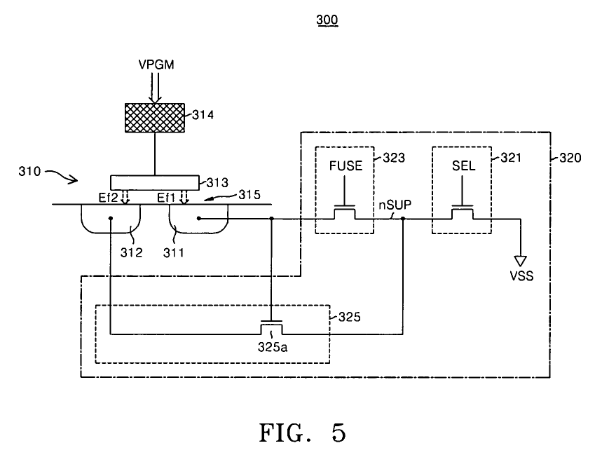

The electric field control unit 220 performs a control operation so that an electric field is formed in the anti-fuse device 210 at the time of the anti-fusing operation. The formation of an electric field Ef1 between the gate terminal 213 and first junction 211 of the anti-fuse device 210 and the formation of an electric field Ef2 between the gate terminal 213 and second junction 212 of the anti-fuse device 210 are separately controlled as shown in FIG. 4.

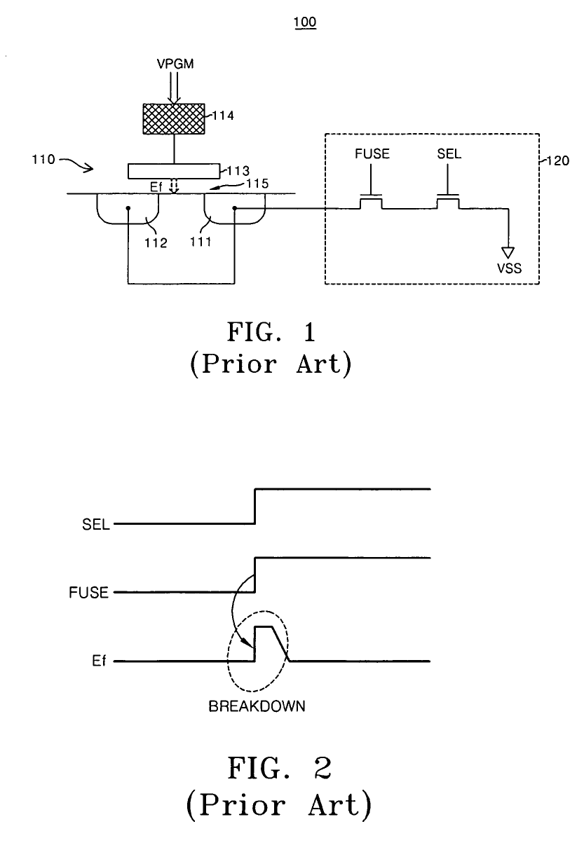

The formation of the electric field Ef1 at the first junction 211 and the formation of the electric field Ef2 at the second junction 212 are separately controlled, thus causing a breakdown in the insulating layer 215 at two points of the anti-fuse device 210. Therefore, the anti-fuse circuit 200 of the present disclosure can improve reliability compared to the anti-fuse circuit 100 of FIG. 1.

With reference to FIGS. 3 and 4, the electric field control unit 220 includes a fuse selection means 221, a first junction control means 223 and a second junction control means 225.

The fuse selection means 221 provides a predetermined voltage, ground voltage VSS in FIG. 3, to a voltage supply terminal nSUP in response to a fuse selection signal SEL. If the anti-fuse device 210 is selected and the fuse selection signal SEL makes a transition to a logic H level at the time of the anti-fusing operation, the ground voltage VSS is provided to the voltage supply terminal nSUP.

The first junction control means 223 is controlled so that a first voltage is applied to the first junction 211 of the anti-fuse device 210 in response to a first fusing signal FUSE1. As shown in FIG. 3, the first voltage is the ground voltage VSS. When the first fusing signal FUSE1 is activated to a logic H level, the electric field Ef1 is formed between the gate terminal 213 and first junction 211 of the anti-fuse device 210, causing a first breakdown, as shown in FIG. 4.

The second junction control means 225 is controlled so that a second voltage is applied to the second junction 212 of the anti-fuse device 210 in response to a second fusing signal FUSE2. As shown in FIG. 3, the second voltage is also the ground voltage VSS. If the first fusing signal FUSE1 is deactivated to a logic L level and the second fusing signal FUSE2 is activated to a logic H level after the first breakdown occurs, the electric field Ef2 is formed between the gate terminal 213 and second junction 212 of the anti-fuse device 210, causing a second breakdown, as shown in FIG. 4.

By the electric field control unit 220, the electric field Ef1 at the first junction 211 and the electric field Ef2 at the second junction 212 can be separately controlled and a breakdown of the insulating layer 215 can occur at two points.

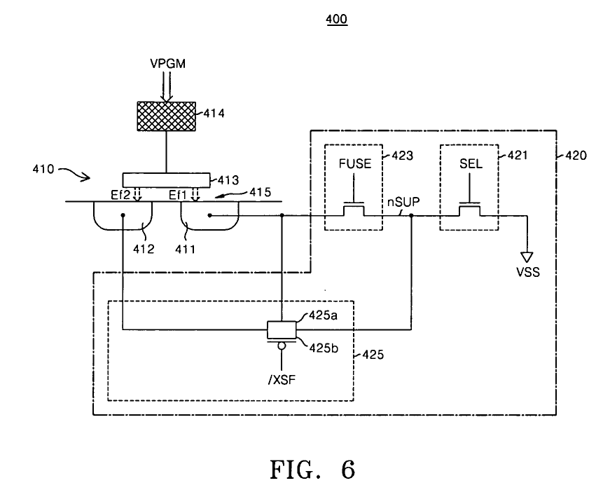

FIG. 5 is a view of an anti-fuse circuit 300 according to an embodiment of the present disclosure, which shows a modification of the anti-fuse circuit 200 of FIG. 3. Similar to the anti-fuse circuit 200 of FIG. 3, the anti-fuse circuit 300 of FIG. 5 includes an anti-fuse device 310 and an electric field control unit 320. The anti-fuse device 310 of FIG. 5 is the same as the anti-fuse device 210 of FIG. 3.

Similar to the electric field control unit 220 of FIG. 3, the electric field control unit 320 of FIG. 5 includes a fuse selection means 321, a first junction control means 323, and a second junction control means 325. The fuse selection means 321 of FIG. 5 is the same as the fuse selection means 221 of FIG. 3.

Similar to the first junction control means 223 of FIG. 3, the first junction control means 323 of FIG. 5 is controlled so that the ground voltage VSS is applied to the first junction 311 of the anti-fuse device 310. The first fusing signal FUSE1 of FIG. 3 is a signal that makes a transition to a logic L level after making a transition to a logic H level for a predetermined period of time. A fusing signal FUSE of FIG. 5 is a signal that continuously maintains a logic H level at the time of the anti-fusing operation.

Similar to the second junction control means 225 of FIG. 3, the second junction control means 325 of FIG. 5 is also controlled so that the ground voltage VSS is applied to the second junction 312 of the anti-fuse device 310. The second junction control means 325 of FIG. 5 responds to the breakdown occurring between the gate terminal 313 and the first junction 311 of the anti-fuse device 310. If breakdown occurs between the gate terminal 313 and the first junction 311 of the anti-fuse device 310, the voltage of the first junction 311 increases. At this time, the ground voltage VSS is provided to the second junction 312.

Preferably, the second junction control means 325 includes an NMOS transistor 325a. The NMOS transistor 325a is gated in response to a signal that is generated at the first junction 311 at the time of breakdown, thus providing the ground voltage VSS to the second junction 312.

Also, in the anti-fuse circuit 300 of FIG. 5, electric fields Ef1 and Ef2 at the first and second junctions 311 and 312 are separately controlled, and a breakdown in the insulating layer 215 can occur at two points. Also, in the anti-fuse circuit 300 of FIG. 5, reliability is increased.

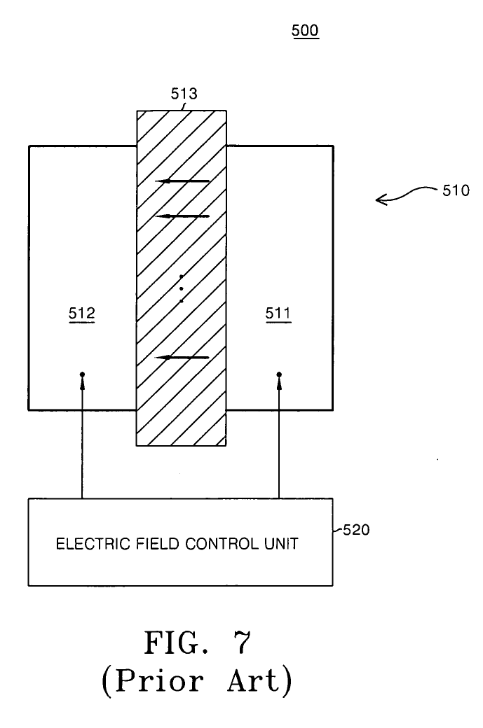

FIG. 6 is a view of an anti-fuse circuit 400 according to an embodiment of the present disclosure, which shows an embodiment for supplementing the anti-fuse circuit 300 of FIG. 5. The anti-fuse circuit 400 of FIG. 6 is substantially similar to the anti-fuse circuit 300 of FIG. 5. The anti-fuse circuit 400 of FIG. 6 includes a P-type metal oxide semiconductor (PMOS) transistor 425b in a second junction control means 425.

The PMOS transistor 425b is gated in response to a supplement control signal /XSF. The PMOS transistor 425b is arranged in parallel to an N-type metal oxide semiconductor (NMOS) transistor 425a between a second junction 412 and a power supply terminal nSUP.

As shown in FIG. 6, an electric field is formed between the second junction 412 and a gate terminal 413 to cause a first breakdown even when a second breakdown does not occur between a first junction 411 and the gate terminal 413. If the supplement control signal /XSF is activated to a logic L level, the PMOS transistor 425b is turned on, and an electric field is formed between the second junction 412 and the gate terminal 413 to cause the first breakdown.

In an anti-fuse device having a MOS structure, the shape of a gate terminal can be variously modified to easily cause gate breakdown.

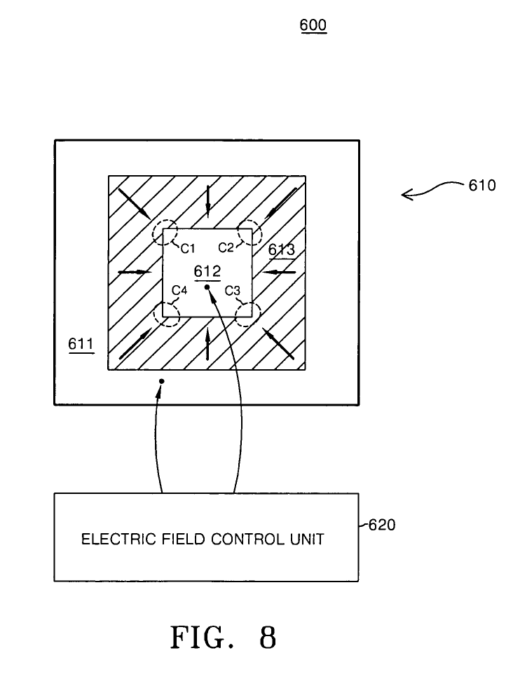

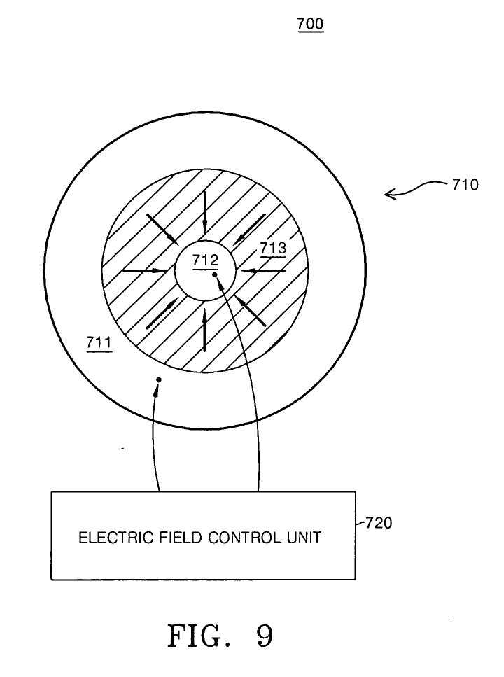

Anti-fuse circuits 600 and 700 shown in FIGS. 8 and 9 are proposed to improve the anti-fuse circuit 500 of FIG. 7. FIG. 8 is a view showing the anti-fuse circuit 600 according to an embodiment of the present invention. Referring to FIG. 8, the anti-fuse circuit 600 includes an anti-fuse device 610 and an electric field control unit 620.

The anti-fuse device 610 is formed in a MOS structure having a first junction 611, a second junction 612 and a gate terminal 613. In this case, the gate terminal 613 of the anti-fuse device 610 is implemented in the form of a band-shaped closed circuit.

In the embodiment of FIG. 8, the gate terminal 613 of the anti-fuse device 610 is formed in a rectangular band shape. As shown in FIG. 8, the gate terminal 613 formed in a rectangular band shape can cause breakdown because an adequate electric field is formed at the inner corner portions c1, c2, c3 and c4 of the gate terminal 613.

The electric field control unit 620 performs a control operation so that electric fields are formed between the first junction 611 and the second junction 612, respectively.

FIG. 9 is a view showing the anti-fuse circuit 700 according to an embodiment of the present disclosure. The anti-fuse circuit 700 of FIG. 9 is similar to the anti-fuse circuit 600 of FIG. 8. The anti-fuse circuit 700 includes a gate terminal 713 of an anti-fuse device 710 formed in a circular band shape. The gate terminal 713 having the shape of FIG. 9 can cause breakdown because an adequate electric field can be formed at an inner junction 712.

The construction other elements of the anti-fuse circuit of FIG. 9 is the same as that of FIG. 8.

Although preferred embodiments of the present invention have been disclosed for illustrative purposes, those skilled in the art will appreciate that various modifications, additions and substitutions are possible, without departing from the scope and spirit of the invention as disclosed in the accompanying claims.

In the anti-fuse circuit and anti-fusing method according to embodiments of the present disclosure, the formation of an electric field at the first junction of an anti-fuse device and the formation of an electric field at the second junction are separately controlled, so that a breakdown of an insulating layer can occur at two points. Therefore, the anti-fuse circuit of the present disclosure can improve reliability compared to a conventional anti-fuse circuit.

Further, in anti-fuse circuits according to embodiments of the present disclosure, the gate terminal of an anti-fuse device is implemented in the form of a band-shaped closed circuit and the breakdown of the gate terminal can be performed.

What is claimed is:

1. An anti-fuse circuit, comprising:
an anti-fuse device having a first junction, a second junction and a gate terminal; and
an electric field control unit for performing a control operation wherein an electric field is formed in the anti-fuse device at a time of an anti-fusing operation, the electric field control unit being driven wherein formation of a first electric field between the gate terminal and first junction of the anti-fuse device and formation of a second electric field between the gate terminal and second junction of the anti-fuse device are separately controlled.

2. The anti-fuse circuit according to claim 1, wherein the electric field control unit comprises:
first junction control means being controlled wherein a first voltage is provided to the first junction of the anti-fuse device in response to a first fusing signal; and
second junction control means being controlled wherein a second voltage is provided to the second junction of the anti-fuse device in response to a second fusing signal.

3. The anti-fuse circuit according to claim 2, wherein the first and second voltages are the same.

4. The anti-fuse circuit according to claim 1, wherein the electric field control unit comprises:
first junction control means being controlled wherein a first voltage is provided to the first junction of the anti-fuse device in response to a fusing signal; and
second junction control means being controlled wherein a second voltage is provided to the second junction of the anti-fuse device in response to breakdown occurring between the gate terminal and the first junction of the anti-fuse device.

5. The anti-fuse circuit according to claim 4, wherein the second junction control means comprises an N-type metal oxide semiconductor transistor that is gated in response to a signal of the first junction, and provides the second voltage to the second junction of the anti-fuse device.

6. The anti-fuse circuit according to claim 5, wherein the second junction control means further comprises a P-type metal oxide semiconductor transistor that is gated in response to a supplement control signal and arranged between a voltage supply terminal for providing the second voltage and the second junction, the P-type metal oxide semiconductor transistor being arranged in parallel to the N-type metal oxide semiconductor transistor.

7. The anti-fuse circuit according to claim 1, wherein the anti-fuse device has a metal oxide semiconductor structure.

8. An anti-fusing method using an anti-fuse circuit that includes an anti-fuse device formed having a metal oxide semiconductor structure including a first junction, a second junction and a gate terminal, comprising:
forming a first electric field between the gate terminal and the first junction of the anti-fuse device at a first time point; and
forming a second electric field between the gate terminal and the second junction of the anti-fuse device at a second time point;
wherein the first and second time points have a predetermined time interval therebetween.

9. The anti-fusing method of claim 8, further comprising applying a first voltage to the first junction in response to a first fusing signal.

10. The anti-fusing method of claim 8, further comprising applying a second voltage to the second junction in response to a second fusing signal.

11. The anti-fusing method of claim 8, wherein forming the second electric field further comprises deactivating the first electric field.

12. An anti-fuse circuit, comprising:
an anti-fuse device having a first junction, a second junction and a gate terminal; and
an electric field control unit for performing a control operation wherein an electric field is formed between the first and second junctions of the anti-fuse device at a time of an anti-fusing operation;
wherein the gate terminal of the anti-fuse device is implemented in the form of a band-shaped closed circuit.

13. The anti-fuse circuit according to claim 12, wherein the gate terminal of the anti-fuse device is formed in a rectangular band shape.

14. The anti-fuse circuit according to claim 12, wherein the gate terminal of the anti-fuse device is formed in a circular band shape.

15. The anti-fuse circuit according to claim 12, wherein the anti-fuse device has a metal oxide semiconductor structure.
